(19) United States
(12) Patent Application Publication
(10) Pub. No.: US 2026/0359543 A1
(43) Pub. Date: Nov. 12, 2026

(54) ADVANCED MIXED ROW DESIGN WITH IMPLANTATION LAYER BASED SITE ROW

(71) Applicant: Samsung Electronics Co., Ltd., Gyeonggi-do (KR)

(72) Inventors: Sandra Maria SHAJI, Santa Clara, CA (US); Xuelian ZHU, San Jose, CA (US); Victor HUANG, Sunnyvale, CA (US); Subin CHOI, Sunnyvale, CA (US); Harsono SIMKA, Saratoga, CA (US)

(21) Appl. No.: 19/429,432

(22) Filed: Dec. 22, 2025

Related U.S. Application Data
(60) Provisional application No. 63/802,931, filed on May 9, 2025.

(51) Int. Cl. G06F 30/392

(52) U.S. Cl. CPC G06F 30/392

(57) ABSTRACT

A semiconductor design technique and device architecture are disclosed in which site rows are defined by implantation layers rather than by cell height. The implantation layers, including a short implantation layer and a tall implantation layer, are arranged in a uniform vertical pattern aligned with corresponding P/N boundaries in a semiconductor substrate. Standard cells of three distinct heights—short, medium, and tall—are disposed on the site rows to form a mixed-row structure with uniform implantation alignment. The medium cell height is defined as an intermediate value between the short and tall cell heights, providing balanced drivability and improved patterning consistency. In some embodiments, the medium cells are configured with balanced or unbalanced PFET and NFET dimensions to optimize performance, power, and area (PPA). The disclosed structure reduces implantation variation, enhances layout uniformity, and improves overall manufacturability and electrical performance of advanced semiconductor devices.

### CROSS-REFERENCE TO RELATED APPLICATION

This application claims the priority benefit under 35 U.S.C. § 119(e) of U.S. Provisional Application No. 63/802,931, filed on May 9, 2025, the disclosure of which is incorporated by reference in its entirety as if fully set forth herein.

### TECHNICAL FIELD

The disclosure generally relates to methods of fabricating semiconductor devices. More particularly, the subject matter disclosed herein relates to improvements in advanced mixed row architecture techniques for semiconductor design that optimizes area efficiency and/or device performance.

### BACKGROUND

To meet the increased demand for electronic devices with faster speeds and/or lower power consumption, semiconductor devices with high reliability, high performance, and/or multiple functions are desired. To satisfy these types of demands, the complexity and/or integration density of semiconductor devices are being increased, resulting in smaller manufacturing designs and patterns for the semiconductor devices.

In advanced semiconductor design and manufacturing, the scaling of standard cell dimensions is a key driver of circuit density and performance. In particular, newer fabrication processes achieve more compact cell area by aggressively scaling cell height. While this scaling may improve density, it may also reduce the space available for active regions, thereby reducing the drivability of cells.

### SUMMARY

The present disclosure addresses the disadvantages of traditional mixed row design by providing an implantation-layer-based architecture approach.

According to an embodiment, site rows may be defined by implantation layers rather than by cell height, and may be aligned with a P/N boundary (i.e., an interface where p-type and n-type semiconductor materials meet) of an implantation layer. The implantation layers may be arranged in a uniform vertical fashion with two fixed heights: a short implantation layer (S′) and a tall implantation layer (T′).

To accommodate this type of arrangement, according to an embodiment, the present disclosure may incorporate three different cell heights: short (S), medium (M), and tall (T). The medium cell height may be defined as an intermediate value equal to half the sum of the tall and short cell heights. The introduction of this intermediate cell height may provide improved flexibility in cell placement and may address the drivability issues associated with some two-height configurations.

According to an embodiment, two types of advanced mixed row designs may be provided.

In a first type, medium cells may be configured with balanced P-channel field-effect transistor (PFET) and N-channel field-effect transistor (NFET) dimensions, resulting in patterning-friendly implantation and enhanced performance, power, and area (PPA).

In a second type, medium cells may be configured with unbalanced PFET and NFET dimensions, for example, with a “rise” version with wider PFET than NFET and a “fall” version with wider NFET than PFET, thereby providing additional design options tailored to different application requirements.

By basing site rows on implantation layers and incorporating medium-height cells, the techniques of the present disclosure may provide a more patterning-friendly design as a height of the implantation layer is fixed, may reduce the probability of weak short cells driving tall cells, and may improve overall PPA.

In an embodiment, a computer-implemented method of designing a semiconductor architecture comprises defining site rows in a semiconductor layout based on at least one implantation layer; aligning a site row with a P/N boundary of at least one implantation layer; arranging the implantation layers in a vertical fashion with a first implantation height and a second implantation height; and placing cells on the site rows to form a mixed row architecture, wherein the cells includes a first cell having a first cell height, a second cell having a second cell height, and a third cell having a third cell height.

In an embodiment, a semiconductor device comprises a semiconductor substrate having implantation layers including a first implantation layer and a second implantation layer arranged in a vertical pattern; site rows formed on the substrate, a site row being aligned with a P/N boundary of one of the implantation layers; and standard cells disposed on the site rows, the standard cells including: a first cell having a first height, a second cell having a second height, and a third cell having a third height defined as an intermediate value between the first height and the second height, wherein the site rows are defined by the implantation layers and the first, second, and third cells are arranged to form a mixed row structure.

In an embodiment, a system comprises a processor; and memory storing instructions, which when executed, control the processor to: define site rows in a semiconductor layout based on at least one implantation layer; align a site row with a P/N boundary of at least one implantation layer; arrange the implantation layers in a vertical fashion with a first implantation height and a second implantation height; and place cells on the site rows to form a mixed row architecture, wherein the cells includes a first cell having a first cell height, a second cell having a second cell height, and a third cell having a third cell height, wherein the second cell height is equal to one-half the sum of the first and third cell heights.

### BRIEF DESCRIPTION OF THE DRAWING

In the following section, the aspects of the subject matter disclosed herein will be described with reference to exemplary embodiments illustrated in the figures, in which:

FIG. 1 is a block diagram illustrating a computer system for performing a semiconductor design process utilizing an implantation-layer-based architecture approach according to an embodiment.

FIG. 2 is a flow chart illustrating a method of designing and fabricating a semiconductor device utilizing an implantation-layer-based architecture approach according to an embodiment.

FIG. 3 illustrates an advanced mixed row design with an implantation-layer-based site row according to an embodiment.

FIG. 4 is a flow chart illustrating a method of designing a mixed row semiconductor architecture utilizing an implantation-layer-based architecture approach according to an embodiment.

FIG. 5 illustrates a Type 1 advanced mixed row design of a semiconductor device with balanced PFET and NFET medium cells according to an embodiment.

FIG. 6 illustrates a Type 2 advanced mixed row design of a semiconductor device with unbalanced PFET and NFET medium cells according to an embodiment.

FIG. 7 illustrates an example cell placement configuration under a Type 2 advanced mixed row design of a semiconductor device according to an embodiment.

FIG. 8 illustrates a mixed row design according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures(including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

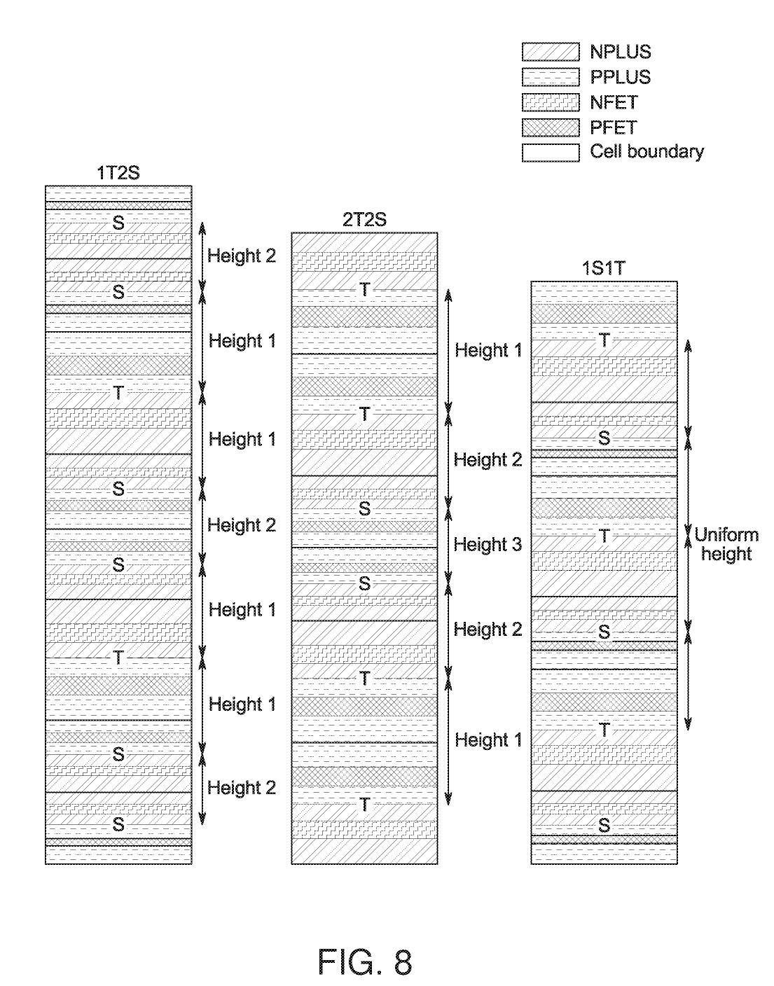

One approach used to balance a compact design area with adequate performance is mixed row architecture. In some mixed row designs, tall and short cells are placed on their respective site rows in a uniform fashion, using configurations such as 1T2S, 2S2T or 1S1T. These types of arrangements are illustrated in FIG. 8, where “S” represents short cells and “T” represents tall cells. A short cell (S) is a standard cell having the smallest vertical dimension and is typically used for area efficiency but has weaker drivability. A tall cell (T) is a standard cell with the largest vertical dimension and provides stronger drivability but consumes more area.

However, as shown in FIG. 8, traditional mixed row design may suffer from several disadvantages. The implantation layer may not be patterning friendly. Even though only two cell heights (tall and short) are used, different configurations can result in different implantation heights.

For example, a 1T2S configuration may produce two different implantation heights, e.g., Height1 and Height 2, a 2T2S configuration may produce three different implantation heights, e.g., Height1, Height 2, and Height 3, and a 1S1T configuration may produce only one implantation height, e.g., uniform height.

In addition, because only two cell heights are available, there are no intermediate-height cells. This can have a potential impact on performance, power, and area (PPA), since weak short cells may be required to drive tall cells. For example, the probability of a weak cell driving a tall cell is higher in the 1S1T configuration, as short cells always abut tall cells.

The present disclosure provides a more patterning-friendly mixed row design that addresses these types of disadvantages while providing additional flexibility in cell placement and improved performance, power, and area (PPA).

A semiconductor design technique and device architecture are disclosed in which site rows are defined by implantation layers rather than by cell height. The implantation layers, including a short implantation layer and a tall implantation layer, are arranged in a uniform vertical pattern aligned with corresponding P/N boundaries in a semiconductor substrate. Standard cells of three distinct heights—short, medium, and tall—are disposed on the site rows to form a mixed-row structure with uniform implantation alignment. The medium cell height is defined as an intermediate value between the short and tall cell heights, providing balanced drivability and improved patterning consistency. In some embodiments, the medium cells are configured with balanced or unbalanced PFET and NFET dimensions to optimize performance, power, and area (PPA). The disclosed structure reduces implantation variation, enhances layout uniformity, and improves overall manufacturability and electrical performance of advanced semiconductor devices.

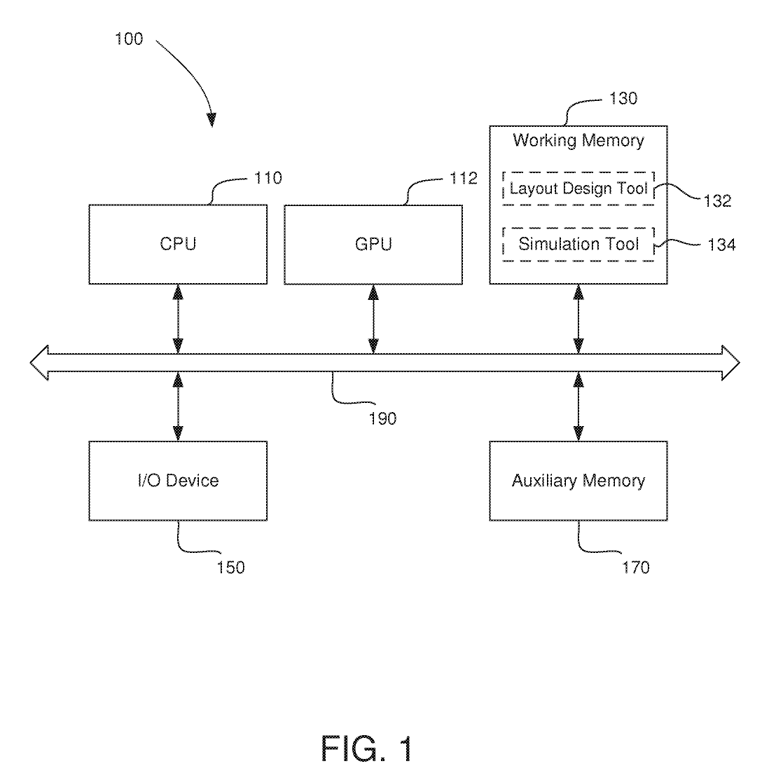

FIG. 1 is a block diagram illustrating a computer system 100 configured to perform a semiconductor design process that implements the implantation-layer-based row framework disclosed herein, according to some embodiments of the present disclosure.

Referring to FIG. 1, the computer system 100 may include a central processing unit (CPU) 110, a graphic processing unit (GPU) 112, a working memory 130, an input-output device 150, and an auxiliary memory device 170. In some embodiments, the computer system 100 may be a customized system for performing a layout design process. These components cooperate to execute an electronic design automation (EDA) environment capable of implementing the mixed-row implantation-aligned row framework. Furthermore, the computer system 100 may be configured to execute various designs and check simulation programs.

The CPU 110 may be configured to run a variety of software programs, such as application programs, operating systems, and/or device drivers. For example, the CPU 110 may be configured to run an operating system (not shown) loaded on the working memory 130. Furthermore, the CPU 110 may be configured to run various application programs on the operating system. For example, the CPU 110 may be configured to run a layout design tool 132 and/or a simulation tool 134 loaded on the working memory 130. Optionally, GPU 112 may be configured to run the layout design tool 132 and/or the simulation tool 134 loaded on the working memory 130 to offload parallel computations with the CPU 110 and lessen the computing burden of the CPU 110. The CPU 110 and GPU 112 may execute the layout design tool 132 to define site rows according to implantation-layer boundaries and to align each site row with a corresponding P/N boundary of the substrate model. The layout design tool 132 may further implement the uniform vertical arrangement of short and tall implantation heights and may manage placement of short, medium, and tall cells on those site rows.

The operating system or application programs may be loaded on the working memory 130. For example, when the computer system 100 starts a booting operation, an operating system image stored in the auxiliary memory device 170 may be loaded on the working memory 130 according to a booting sequence. In the computer system 100, overall input/output operations may be managed by the operating system.

Some application programs, which may be selected by a user and/or be provided for basic services, may be loaded on the working memory 130. According to some embodiments of the present disclosure, the layout design tool 132 and/or optical proximity correction (OPC) tool 134 may be loaded on the working memory 130, from the auxiliary memory device 170.

The layout design tool 132 may provide a function for changing biasing data for specific layout patterns. For example, the layout design tool 132 may be configured to allow the specific layout patterns to have shapes and positions different from those defined by a design rule. The layout design tool 132 may be configured to perform a design rule check (DRC) under the changed condition of the bias data.

The simulation tool 134 may be configured to perform an OPC process on layout data, which is obtained by the layout design tool 132. The simulation or verification tool 134 may further ensure that the resulting cell placement maintains electrical-to-physical alignment across the substrate and satisfies performance, power, and area (PPA) constraints.

The working memory 130 may include one or more volatile memory devices (e.g., static random access memory (SRAM) and/or dynamic random access memory (DRAM) devices) and/or nonvolatile memory devices (e.g., phase-change random access memory (PRAM), magnetoresistive random access memory (MRAM), resistive random access memory (ReRAM), ferroelectric random access memory (FRAM), and/or NOR flash memory devices). The working memory 130 may store data structures representing the implantation layers, site-row definitions, cell-height libraries, and mixed-row placement rules used during execution of the framework.

The input-output device 150 may be configured to control user input and output operations of user interface devices. For example, the input-output device 150 may include a keyboard or a monitor, allowing a designer to input relevant information. The input/output device 150 allows a designer to interact with the system to inspect the implantation-aligned site rows, adjust the proportions of short, medium, and tall cells, and perform placement and routing operations consistent with the implantation-layer-based approach. By using the input-output device 150, the designer may receive information on several regions or data paths, to which adjusted operating characteristics will be applied, of a semiconductor device. The input-output device 150 may be configured to display a progress status or a process result of the OPC tool 134.

The auxiliary memory device 170 may serve as a storage medium for the computer system 100. The auxiliary memory device 170 may be configured to store application programs, an operating system image, and/or various data. The auxiliary memory device 170 may be

provided in the form of one of memory cards (e.g., MultiMediaCard (MMC), embedded MMC (eMMC), Secure Digital (SD), MicroSD, and so forth) or a hard disk drive (HDD). The auxiliary memory device 170 may include a NAND flash memory device with a large memory capacity. In some embodiments, the auxiliary memory device 170 may include at least one of next-generation nonvolatile memory devices (e.g., PRAM, MRAM, ReRAM, or FRAM) or NOR flash memory devices. The auxiliary memory device 170 may store the cell libraries, implantation-layer templates, and design rules, including the definitions of medium-height cells derived from the short and tall cell heights.

A system interconnector 190 may serve as a system bus for realizing a network in the computer system 100. The CPU 110, the working memory 130, the input-output device 150, and the auxiliary memory device 170 may be connected to each other through the system interconnector 190, and thus, data may be exchanged therebetween. However, the system interconnector 190 may not be limited to the previously described configuration. For example, it may further include one or more additional elements for increasing efficiency in data communication.

Accordingly, the computer system 100 provides the hardware and software environment for implementing the implantation-layer-based design methodology described herein, including defining site rows from implantation layers, arranging short-height and tall-height implantation layers in a uniform vertical pattern, and placing S/M/T cells to form an implantation-aligned mixed-row layout.

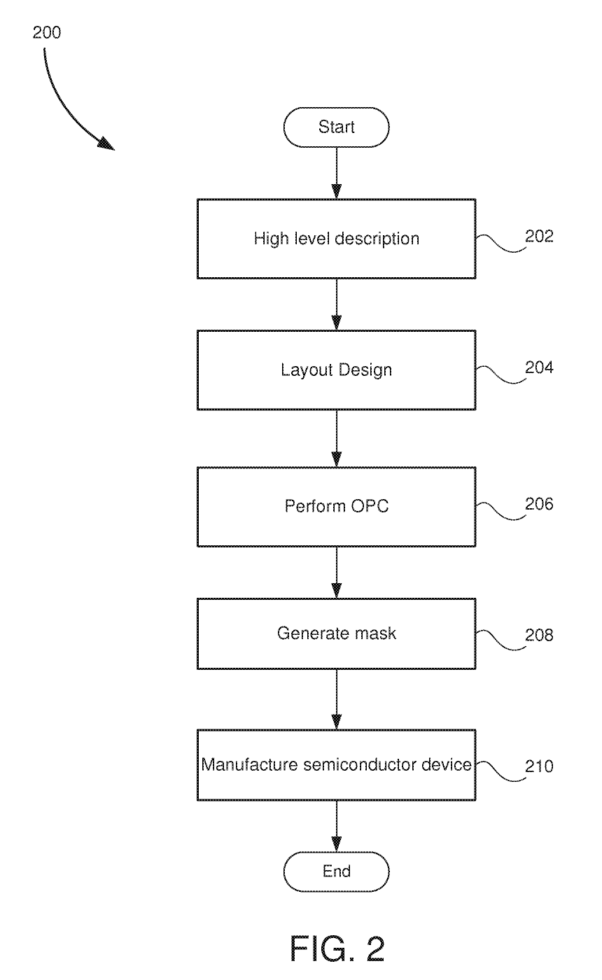

FIG. 2 is a flow chart illustrating a method 200 of designing and fabricating semiconductor devices, according to some embodiments of the present disclosure.

It is to be appreciated that the design process of the semiconductor device is or corresponds to an operation of designing a layout for a circuit, and may be performed using a tool for designing a circuit, e.g., layout design tool 132. The tool may be a program including a plurality of instructions executed by a CPU 110 and/or GPU 112. Accordingly, the designing operation of the semiconductor device may be or may include a computer implemented operation for designing a circuit.

Referring to FIG. 2, a design process for a semiconductor integrated circuit may be performed using the computer system 100 described with reference to FIG. 1, in step 202. For example, in the design process, an integrated circuit to be designed may be described in terms of a computer language (e.g., C language, Very High Speed Integrated Circuit Hardware Description Language (VHDL), Verilog, etc.). Circuits designed by this design process may be more concretely described by a register transfer level (RTL) coding or a simulation. Furthermore, codes generated by the RTL coding may be converted into a netlist, and the results may be combined with each other to wholly describe a semiconductor device. The combined schematic circuit may be verified by a simulation tool.

In certain embodiments, an adjusting step may be further performed, based on a result of the verification step.

A layout design process may be performed to realize a logically complete form of the semiconductor integrated circuit on a silicon wafer, in step 204. For example, the layout design process may be performed, based on the schematic circuit prepared in the design process or the corresponding netlist. The layout design process may include a routing step of placing and connecting various standard cells that are provided from a cell library, based on a predetermined design rule.

In some embodiments, the layout design process may include a floorplan operation, a power plan operation, a placement operation, and a clock tree synthesis (CTS) operation, a routing operation, and a virtual analysis (what-if-analysis) operation.

The floor plan operation may be or correspond to an operation of performing physical designing by cutting and moving a logically designed schematic circuit. In the floor plan operation, a memory and/or a functional block may be disposed. In the floor plan operation, for example, functional blocks to be disposed adjacent to each other may be identified, and space for the functional blocks may be allocated in consideration of available space, required performance and the like. For example, the floor plan operation may include generating a site-row and forming a metal routing track on the generated site-row. The site-row may be or may include a frame for disposing standard cells stored in a cell library according to a prescribed design rule. Standard cells having the same height may be disposed in respective rows. A site for disposing the standard cells may be provided such that standard cells of some rows may have a height different from that of standard cells of other rows.

The power plan operation may be an operation of disposing patterns of wirings connecting a local power source, for example, a driving voltage and/or a ground, to the disposed functional blocks. The placement operation is an operation of disposing patterns of elements constituting the functional block, and may include disposing standard cells. The CTS operation may be or correspond to an operation of generating patterns of signal lines of a center clock related to a response time determining the performance of the semiconductor device. Subsequently, the routing operation may be or correspond to an operation of generating a routing structure or an upper wiring structure including second wiring lines connecting the disposed standard cells. The virtual analysis operation may be or correspond to an operation of verifying and correcting the generated layout.

An OPC step may be performed, in step 206. The OPC step may be performed to correct optical proximity effects, which may occur when a photolithography process is performed on a silicon wafer using a photomask manufactured based on the layout. The optical proximity effect may be an unintended optical effect (such as wave coupling or diffraction) which may occur in the exposing process using the photomask manufactured based on the layout. In the OPC step 206, the layout may be modified to have a reduced difference in shape between designed patterns and actually-formed patterns, which may be caused by the optical proximity effects. As a result of the OPC step 206, the shapes and positions of patterns in the designed layout may be changed or biased.

A photomask may be manufactured, based on the layout modified by the OPC step, in step 208.

The manufactured photomask may be used to manufacture a semiconductor device, in step 210. In the actual fabricating process, the exposing and etching steps may be repeatedly performed, and thus, patterns defined in the layout design process may be sequentially formed on a semiconductor substrate, for example, a silicon wafer.

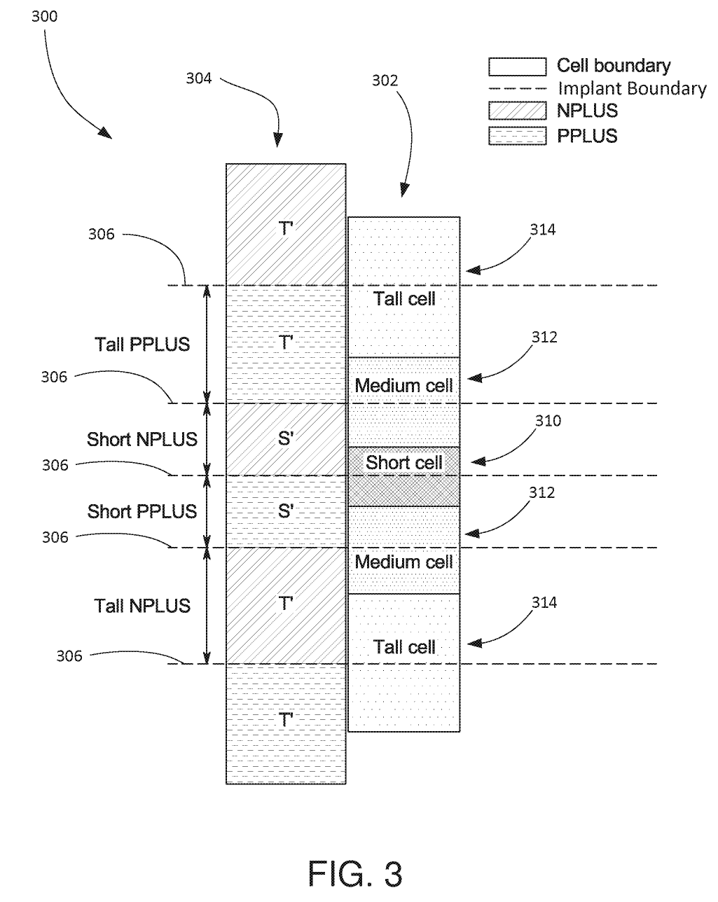

FIG. 3 illustrates an advanced mixed row design according to an embodiment.

Referring to FIG. 3, an embodiment of an advanced mixed row design 300 is illustrated in accordance with the present disclosure. In contrast to conventional mixed-row architecture, where the physical site rows are defined by cell height, the configuration in FIG. 3 defines site rows 302 based on the positions of implantation layers 304 that are aligned with P/N boundaries 306 in the semiconductor substrate. This arrangement allows the layout to be defined by the underlying doping regions rather than by arbitrary cell heights, thereby producing a patterning-friendly and lithographically consistent architecture.

It is to be appreciated, as known in the art, an implantation layer is a doped semiconductor region created by ion implantation to define device areas such as wells or source/drain terminal, a site row is a row in an architecture that defines the vertical placement of standard cells and a P/N boundary is a the junction between a p-type region and an n-type region in a semiconductor substrate. Furthermore, in the figures, NPLUS refers to a heavily doped n-type region formed by implanting donor impurities (e.g., phosphorus, arsenic) at high concentration, while PPLUS refers to a heavily doped p-type region formed by implanting acceptor impurities (e.g., boron) at high concentration.

Each implantation layer 304 may correspond to a doped semiconductor region—such as a well, source, or drain—formed by ion implantation. The P/N boundaries 306 represent junction interfaces between p-type and n-type regions. By aligning site rows 302 precisely with these P/N boundaries, the disclosed structure ensures accurate overlay between the electrical and physical layers, reducing variation caused by misalignment or non-uniform implantation depth.

Two implantation heights are provided, a short implantation height (S′) and a tall implantation height (T′), which are placed in a uniform vertical fashion. To accommodate this structure, three types of cells are employed: short cells (S) 310, medium cells (M) 312, and tall cells (T) 314. The medium cell height is defined as an intermediate value equal to one-half the sum of the tall cell height and the short cell height. The medium cell (M) 314 provides a balanced option between area utilization and drivability. By employing two uniform implantation heights—short (S′) and tall (T′), a more patterning-friendly layout is enabled. This intermediate cell (or medium cell) option addresses the shortcomings of traditional approaches, which lack mid-height cells and often face performance limitations due to weaker short cells driving taller cells.

As illustrated in FIG. 3, the short, medium, and tall cells are disposed on the respective site rows 302, conforming to the implantation-layer pattern 304 and maintaining consistent alignment with the P/N boundaries 306. This arrangement offers several advantages over traditional mixed-row schemes. Because the implantation heights are uniform and independent of the number of cell types, implantation patterning complexity is reduced. Furthermore, the incorporation of the intermediate medium cell (M) minimizes the likelihood that a weak short cell will drive a tall cell, thereby enhancing PPA characteristics.

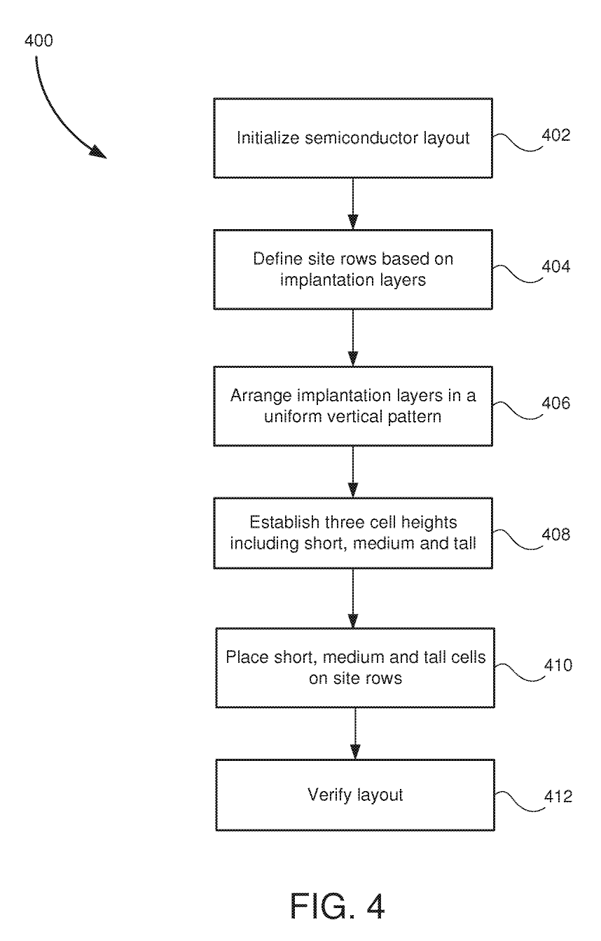

FIG. 4 illustrates a flow diagram of a method 400 for designing a mixed-row semiconductor architecture in accordance with the present disclosure.

Referring to FIG. 4, the method begins at step 402, where a semiconductor layout is initialized within an electronic design automation (EDA) environment, for example, system 100 as shown in FIG. 1.

At step 404, site rows are defined based on implantation layers instead of cell height, establishing the foundational vertical structure of the design. Each site row is aligned with a corresponding P/N boundary of an implantation layer to ensure physical consistency between the logical layout and substrate doping profiles.

At step 406, the implantation layers are arranged in a uniform vertical pattern having two fixed implantation heights, a short implantation height (S′) and a tall implantation height (T′).

At step 408, three standard-cell heights—short (S), medium (M), and tall (T)—are established within the design library, with the medium height set as an intermediate value between the short and tall heights.

At step 410, the layout tool performs placement of short, medium, and tall cells onto the corresponding site rows according to the implantation-layer pattern. This placement forms a mixed-row arrangement that minimizes implantation variation while maintaining compact cell area.

At step 412, the layout is verified and optimized to achieve improved performance, power, and area characteristics.

The sequence shown in FIG. 4 thus illustrates how defining site rows by implantation layers, rather than by cell height, produces a patterning-friendly mixed-row design that enhances both manufacturability and device performance.

illustrates a Type 1 advanced mixed row design with balanced PFET and NFET medium cells according to an embodiment.

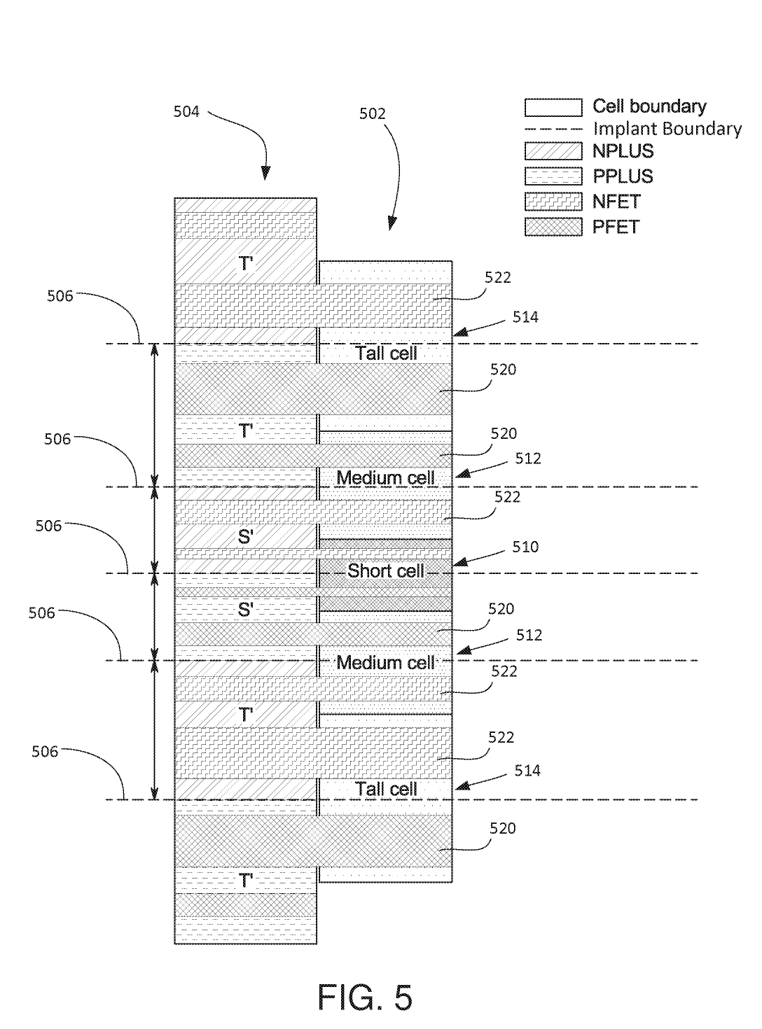

Referring to FIG. 5, the implantation layers 504 are arranged in a uniform vertical pattern following a 2T′2S′ implantation arrangement, in which two tall implantation heights (T′) alternate with two short implantation heights (S′). The site rows 502 are correspondingly aligned with the P/N boundaries 506 of the implantation layers 504.

In this embodiment, the medium cells 512 are configured with balanced PFET 520 and NFET 522 dimensions, i.e., the PFET and NFET dimensions are symmetrical providing stable electrical performance, e.g., providing similar/symmetrical delay to both rise and fall input signal transitions. In the balanced configuration, the PFET and NFET of the medium cell are sized such that their respective drive strengths, switching characteristics, and current capabilities are substantially symmetrical. This proportional sizing provides a neutral transition behavior in which neither the pull-up nor the pull-down network dominates, thereby improving timing uniformity between rising and falling signal edges. As illustrated, the short cells 510, medium cells 512, and tall cells 514 are disposed on corresponding site rows 502 in alignment with the implantation-layer pattern 504. The placement follows a fixed 2T′2S′ implantation configuration, providing a patterning-friendly arrangement since the heights of the S′ and T′ implantation layers are fixed. The availability of the intermediate medium cell height allows for improved transitions between tall and short cells, thereby enhancing PPA characteristics compared to a conventional mixed row architecture.

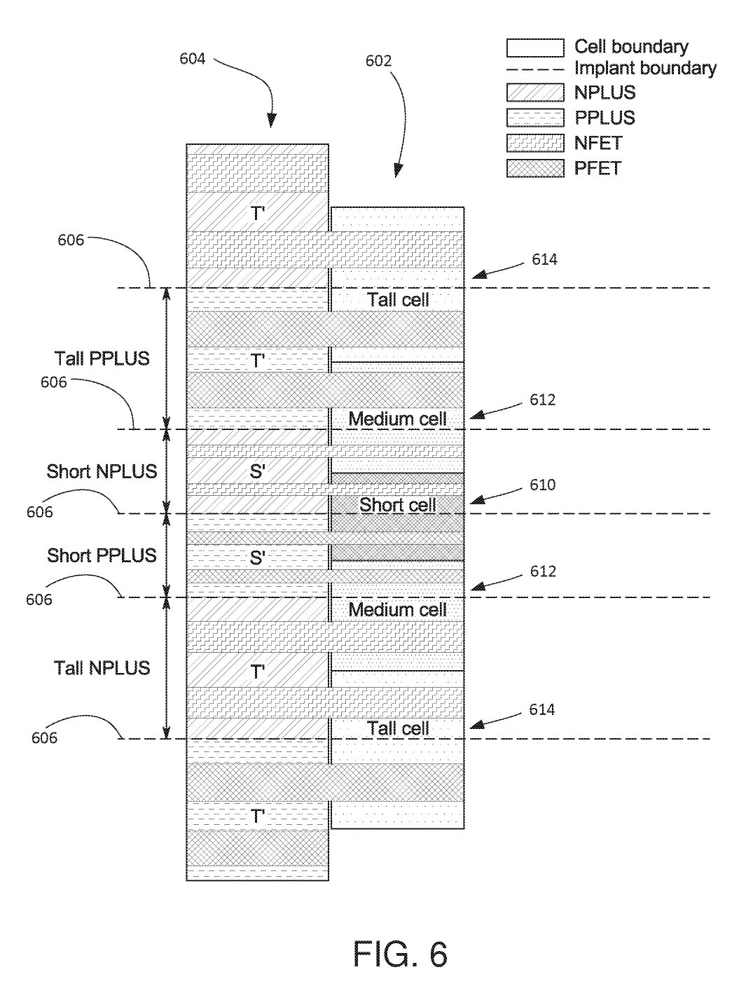

FIG. 6 illustrates a Type 2 advanced mixed row design with unbalanced PFET and NFET medium cells according to an embodiment. As used herein, an “unbalanced” medium cell refers to a medium-height standard cell in which the PFET and NFET are intentionally sized with different channel widths to produce asymmetric drive strengths. Two forms of unbalanced medium cells may be employed. A “rise version” medium cell includes a PFET having a wider channel width than that of the NFET, thereby producing stronger pull-up drive strength for improved rising-edge performance. Conversely, a “fall version” medium cell includes an NFET having a wider channel width than that of the PFET, thereby producing stronger pull-down drive strength for improved falling-edge performance.

Referring to FIG. 6, the implantation-layer configuration follows a 2S′2T′ arrangement. As in the Type 1 design, the site rows 602 are defined by the implantation layers 604 and aligned with the P/N boundaries 606, maintaining the structural benefits of uniform implantation alignment.

In this embodiment, the medium cells 612 are configured with unbalanced PFET and NFET dimensions. Two versions of unbalanced medium cells are contemplated: a “rise” version, in which the PFET is wider than the NFET, and a “fall” version, in which the NFET is wider than the PFET. This configuration illustrates a 2S′2T′ implantation arrangement corresponding to a 1T1M1S mixed standard cell configuration. This arrangement may provide greater design flexibility, for example, short cell percentage may be increased for lower power/area, while tall cell percentage may be increased for performance. However, the Type 2 design may introduce potential impacts on PPA due to the unbalanced nature of the medium cells. Additionally, the short implantation height (S′) in Type 2 (S) may differ from that of Type 1 (e.g., (S+M)/2), which can affect implantation patterning.

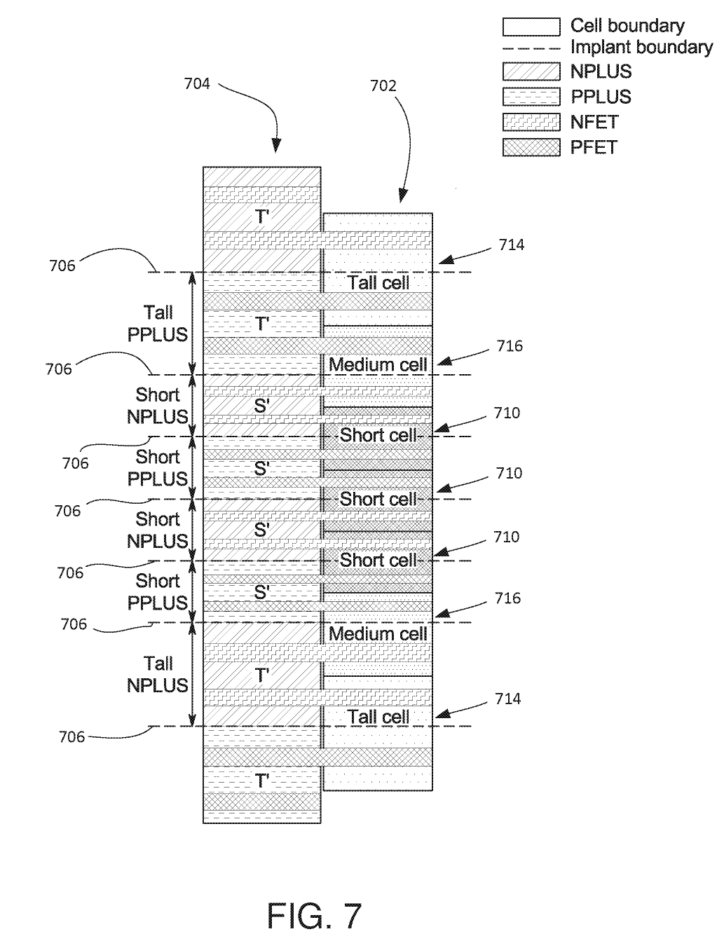

FIG. 7 illustrates an example cell placement configuration under a Type 2 advanced mixed row design according to an embodiment.

Referring to FIG. 7, a 4S′2T′ implantation arrangement corresponds to a 1T1M3S cell configuration, where one tall cell 714, one medium cell 712, and three short cells 710 are sequentially arranged along adjacent site rows 702. The variations shown in FIGS. 6 and 7 enable a designer to select cell proportions according to application requirements. For example, a higher proportion of short cells may be selected to optimize for low power and compact area, while a higher proportion of tall cells may be selected to optimize for performance. Thus, the Type 2 configuration provides additional flexibility despite its potential disadvantages compared to Type 1 by enabling finer control over performance, power, and area (PPA) trade-offs through selective deployment of short, medium, and tall cells while maintaining patterning-friendly uniformity across the semiconductor substrate.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus.

Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus.

A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A computer-implemented method of designing a semiconductor architecture, comprising:
defining site rows in a semiconductor layout based on at least one implantation layer;
aligning a site row with a P/N boundary of at least one implantation layer;
arranging the implantation layers in a vertical fashion with a first implantation height and a second implantation height; and
placing cells on the site rows to form a mixed row architecture,
wherein the cells includes a first cell having a first cell height, a second cell having a second cell height, and a third cell having a third cell height.

2. The method of claim 1, wherein the second cell height is equal to one-half the sum of the first and third cell heights.

3. The method of claim 1, wherein the second cell includes a P-channel field-effect transistor (PFET) and N-channel field-effect transistor (NFET) sized to provide substantially equal conductive drive capabilities.

4. The method of claim 1, wherein the second cell includes a PFET and NFET having different transistor widths such that the PFET and NFET provide different conductive drive capabilities.

5. The method of claim 4, wherein the second cell comprises a rise version in which the PFET has a greater transistor width than the NFET to provide increased PFET conductive drive capability.

6. The method of claim 4, wherein the second cell comprises a fall version in which the NFET has a greater transistor width than the PFET to provide increased NFET conductive drive capability.

7. The method of claim 1, further comprising verifying the placement of the first, second, and third cells by determining alignment between electrical and physical layers of the semiconductor layout.

8. The method of claim 1, wherein the second cell is disposed between the first cell and the third cell and provides a transitional drive capability that reduces mismatch in drivability between the first cell and third cell.

9. The method of claim 1, further comprising adjusting a proportion of the first, second, and third cells to balance performance, power, and area (PPA) characteristics for a given design requirement.

10. The method of claim 1, wherein the height of each implantation layer is fixed such that the first implantation layer and the second implantation layer maintain constant implantation heights across the semiconductor layout.

11. A semiconductor device comprising:
a semiconductor substrate having implantation layers including a first implantation layer and a second implantation layer arranged in a vertical pattern;
site rows formed on the substrate, a site row being aligned with a P/N boundary of one of the implantation layers; and
standard cells disposed on the site rows, the standard cells including:
a first cell having a first height,
a second cell having a second height, and
a third cell having a third height defined as an intermediate value between the first height and the second height,
wherein the site rows are defined by the implantation layers and the first, second, and third cells are arranged to form a mixed row structure.

12. The semiconductor device of claim 11, wherein the third cell has a height equal to one-half the sum of the first height and the second height.

13. The semiconductor device of claim 11, wherein the third cell includes a P-channel field-effect transistor (PFET) and N-channel field-effect transistor (NFET) sized to provide substantially equal conductive drive capabilities.

14. The semiconductor device of claim 11, wherein the third cell includes a PFET and NFET having different transistor widths such that PFET and NFET provide different conductive drive capabilities.

15. The semiconductor device of claim 14, wherein the third cell comprises a rise version in which the PFET has a greater transistor width than the NFET to provide increased PFET conductive drive capability.

16. The semiconductor device of claim 14, wherein the third cell comprises a fall version in which the NFET has a greater transistor width than the PFET to provide increased NFET conductive drive capability.

17. The semiconductor device of claim 11, further comprising verification circuitry or layout alignment features configured to align electrical and physical layers of the semiconductor layout.

18. The semiconductor device of claim 11, wherein the third cell is disposed between the first cell and the second cell and provides a transitional drive capability that reduces mismatch in drivability between the first cell and second cell.

19. The semiconductor device of claim 11, wherein proportions of the first, second, and third cells are selected to balance performance, power, and area (PPA) characteristics for a given design requirement.

20. The semiconductor device of claim 11, wherein heights of the first implantation layer and the second implantation layer are fixed such that constant implantation heights are maintained across the semiconductor layout.

21. A system comprising:
a processor; and
memory storing instructions, which when executed, control the processor to:
define site rows in a semiconductor layout based on at least one implantation layer;
align a site row with a P/N boundary of at least one implantation layer;
arrange the implantation layers in a vertical fashion with a first implantation height and a second implantation height; and
place cells on the site rows to form a mixed row architecture,
wherein the cells includes a first cell having a first cell height, a second cell having a second cell height, and a third cell having a third cell height,
wherein the second cell height is equal to one-half the sum of the first and third cell heights.
